(19) United States
(12) Patent Application Publication
(10) Pub. No.: US 2001/0041258 A1
(43) Pub. Date: Nov. 15, 2001

(54) Standard for a nanotopography unit, and a method for producing the standard

(75) Inventors: Friedrich Passek, Adlkofen (DE); Reinhard Schauer, Laufen (DE); Rudiger Schmolke, Burghausen (DE); Ralf Kumpe, Wedemark (DE)

Correspondence Address: COLLARD & ROE, P.C., 1077 Northern Boulevard, Roslyn, NY, 11576, US

(73) Assignee: WACKER SILTRONIC GESELLSCHAFT FUR HALBLEITERMATERIALIEN AG

(21) Appl. No.: 09/819,961

(22) Filed: Mar. 28, 2001

(30) Foreign Application Priority Data
May 11, 2000 (DE) 100 22 991.3
Sep. 7, 2000 (DE) 100 44 162.9

(51) Int. Cl. C23C 16/00; C23C 14/00

(52) U.S. Cl. 428/332; 428/641; 428/642; 428/446; 428/699; 428/701; 428/702; 427/255.28; 427/569; 427/256

(57) ABSTRACT

A standard for calibrating and checking a nanotopography unit, includes a substrate and at least one structure which is deposited on the substrate. It has a lateral extent of 0.5 to 20 mm and a vertical extent of 5 to 500 nm and is bounded by edges which have a gradient of at most 1*10⁻³. There is also a method for producing the standard, with material being deposited on the substrate at an inhomogeneous deposition rate.

### BACKGROUND OF THE INVENTION

1. Field of the Invention

The present invention relates to a standard for calibrating and checking a nanotopography unit. The present invention also relates to a method for producing such a standard.

2. The Prior Art

New methods for measuring surface topography render it possible to resolve height variations in the nanometer range. Consequently, nanotopography or nanotopology are spoken of in this connection. These measuring methods are beginning to establish themselves as quality control, particularly in the case of the production of semiconductor wafers. However, the lack of calibration standards and checking means is evident here. There are presently no standards available which can be used to carry out a uniform adjustment and checking of the measuring systems. The difficulty consists in reproducibly producing suitable topography structures.

In accordance with the field of use of the measuring instruments, the structures should be elevations or depressions which have lateral extents in the range of 0.5 to 20 mm and a height or depth of 10 to 500 nm. The objective is for the transition from a flat environment to the structures not to be in steps but with gradients of 5*10⁻⁶ to 1*10⁻³.

It is admittedly entirely possible to produce similar structures with corresponding lateral and vertical dimensions (DE 197 09 255 A1). However, their gradient does not correspond to those which are deemed to be relevant to nanotopography. They are therefore scarcely resolved by the nanotopography measuring instruments, or not resolved at all.

Consequently, for the purpose of checking and calibrating measuring instruments use has so far been made of semiconductor wafers from regular production, in the case of which measurable structures are randomly present. However, calibration would have to be done by measuring such a wafer on all existing systems. However, since the systems are being used worldwide by different users, and each of these wafers constitutes a one-off, global calibration is impossible.

### SUMMARY OF THE INVENTION

It is an object of the present invention to provide a reproducible standard with which all measuring instruments can be calibrated and checked.

The above object is achieved according to the present invention by providing a standard for calibrating and checking a nanotopography unit, comprising a substrate and at least one structure which is deposited on the substrate and has a lateral extent of 0.5 to 20 mm and a vertical extent of 5 to 500 nm and which is bounded by edges which have a gradient of at most 1*10⁻³.

The present invention is also directed to a method for producing the standard, comprising depositing a material on the substrate at an inhomogeneous deposition rate.

The present invention permits reproducible access to artificial structures which, not only in their lateral and vertical extent, but in particular with reference to the gradient, are similar to the structures naturally occurring on semiconductor wafers. Thus they can be resolved by nanotopography measuring instruments. The novel method of the invention is distinguished by the fact that it permits the reproducible production of suitable nanotopographic structures, and thus of corresponding standards. In particular, not only the lateral and vertical extent but also the gradient of the structures can be specifically set.

The measuring instruments are surface inspection systems which normally use light from a laser to scan the surface of the device under test (for example a semiconductor wafer made from silicon). These instruments measure the topography with the aid of spatially resolved interferometry and/or detection of the deflection of the reflected light. Mention may also be made of profilometry as a further measuring method. The maximum lateral resolution of the systems is a few 100 μm, while the vertical resolution can be below 1 nm. However, this resolution is substantially determined by the topographic gradient of the structures. Thus, for example, a high step in the case of light which is incident perpendicularly or virtually perpendicularly causes no significant deflection of the reflected light, and is therefore not detected. Such steep nanotopographic structures do not occur on semiconductor wafers which are produced in large batch numbers. Typical nanotopographic structures of interest on semiconductor wafers have lateral extents of 0.5 to 20 mm and heights or depths of 5 to 500 nm. The gradient of the structures is at most 1*10⁻³.

In accordance with the present state of knowledge, most nanotopography structures which can be found on semiconductor wafers are caused by removal processes during the wafer production. Previous attempts to produce such structures reproducibly with the aid of removal processes and to use them as standards have failed. This is because these processes can no longer be adequately monitored in the field of nanotopography.

According to the present invention, the structures are not produced by a removal process, but by the application of material, epitaxy being preferred in particular.

In order to produce the standards, the structures are applied to the flat surface of a substrate, preferably a substrate wafer. The following materials, in particular, can be used as substrate: silicon, GaAs, glass, SiC and quartz. Semiconductor wafers made from silicon and polished on both sides are particularly suitable substrates.

The substrate should have as few natural nanotopology structures as possible, and then only such as are of small vertical extent. It is to be understood in this case that the structures present on the substrate and not intentionally produced should have heights or depths which are smaller by at least a factor of 5 than the structures to be applied according to the invention. For example, for a standard with a lateral extent of 5 mm and a height of 50 nm, the structures present in advance on the substrate should have heights of at most approximately 10 nm given a similar lateral size.

Virtually all substances which can be deposited in pure or mixed form are suitable as deposition material, but in particular the following: silicon, GaAs, germanium, carbon, aluminum, copper, gold, silver, SiO₂, Si₃N₄ and tungsten silicide. It is particularly preferred to deposit silicon.

Suitable deposition processes are: CVD (chemical vapor deposition), electrolytic deposition, plasma coating, evaporation deposition and epitaxy. A particularly preferred deposition method is epitaxy, particularly epitaxial deposition of silicon on a silicon substrate.

The production of suitable nanotopographic structures is effected by an appropriately inhomogeneous deposition rate on the surface of the substrate. In the case of an epitaxy process with silicon, this means that the thickness of the epitaxial layer exhibits local differences. The inhomogeneous deposition of material is influenced by local variation of the parameters determining the deposition rate, or by the use of apertures or covers over the substrate. The shape of the structures is determined by the local distribution of the parameter variations and by the deposition rate, which is a function thereof.

The deposition rates are a function of different parameters, depending on the deposition methods considered. In the case of CVD methods, it is the temperature and the gas pressure which, in particular, determine the deposition rate. In the case of epitaxy, it is above all the temperature, the gas flow, the deposition gases used and their concentration, and the arrangement of the substrate wafer in the deposition reactor. In the case of electrolytic deposition, the deposition rate is a function, in particular, of the temperature, the electric voltage applied and the resistance of the substrate. In the case of plasma coating, the temperature and the acting electric and magnetic fields play the decisive role.

### BRIEF DESCRIPTION OF THE DRAWINGS

Other objects and features of the present invention will become apparent from the following detailed description considered in connection with the accompanying drawing which discloses several embodiments of the present invention. It should be understood, however, that the drawing is designed for the purpose of illustration only and not as a definition of the limits of the invention.

In the drawing, wherein similar reference characters denote similar elements throughout the several views:

FIG. 1 shows a cross sectional view of an epitaxy reactor with a substrate wafer which lies on a susceptor;

FIG. 2 shows a plan view of a susceptor with features of an embodiment of the invention;

FIG. 3 is a cross sectional view of FIG. 2;

FIG. 4 shows a plan view of an epitaxial layer, deposited on a substrate wafer, with structures which are obtained in the case of the use of a susceptor in accordance with FIG. 2;

FIG. 5 is a cross sectional view of FIG. 4;

FIG. 6 shows a plan view of the projection of a deposited structure measured with a nanotopography measuring system; and

FIG. 7 shows the cross sections of structures produced according to the invention which are illustrated graphically.

### DETAILED DESCRIPTION OF PREFERRED EMBODIMENTS

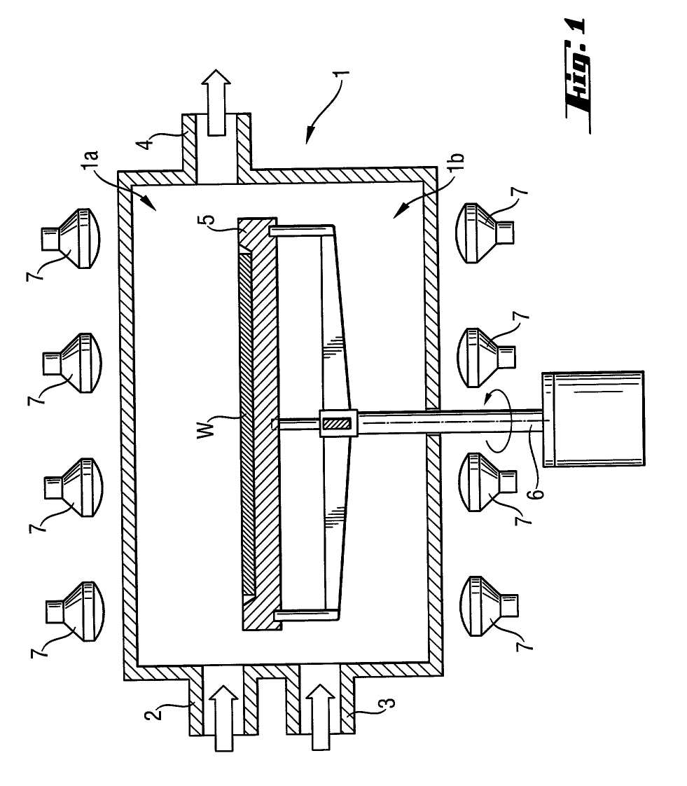

It has already been explained that in the case of silicon epitaxy on a silicon substrate it is, in particular, the temperature of the substrate which is a parameter determining the deposition rate. Temperature gradients on the substrate or inside the substrate or the substrate environment lead to locally differing thicknesses in the deposited layer. FIG. 1 shows a cross sectional view of an epitaxy reactor 1 with a substrate wafer W, which lies on a susceptor 5. Such an epitaxy reactor is typical, and is disclosed, for example, in EP-953 659 A2. The epitaxy chamber 1 normally consists of quartz and is divided by the susceptor 5 into an upper chamber region 1a and a lower chamber region 1b. The reactor 1 also has gas inlet tubes 2 and 3 and a gas outlet tube 4 and is, for example, heated via infrared lamps 7, which are arranged above and below the susceptor. In this case, the supply of energy to the upper side of the substrate is performed by radiation, and the supply of energy to the lower side of the substrate is performed by thermal conduction. The susceptor 5 rests on a rotatable holder 6.

According to the invention, the local temperature of the substrate is specifically influenced, and the local thickness of the epitaxial layer is prescribed in this way. A local temperature gradient can be produced both by differences between the radiant energy fed from above and below, and by using susceptors with regions of different thermal conductivity, different emission behavior, or both. It is also possible to implement a combination of the said options.

According to an embodiment of the invention, the emission behavior or the heat transmission of the susceptor is varied by locally differing surface treatments such as polishing, roughening or silvering.

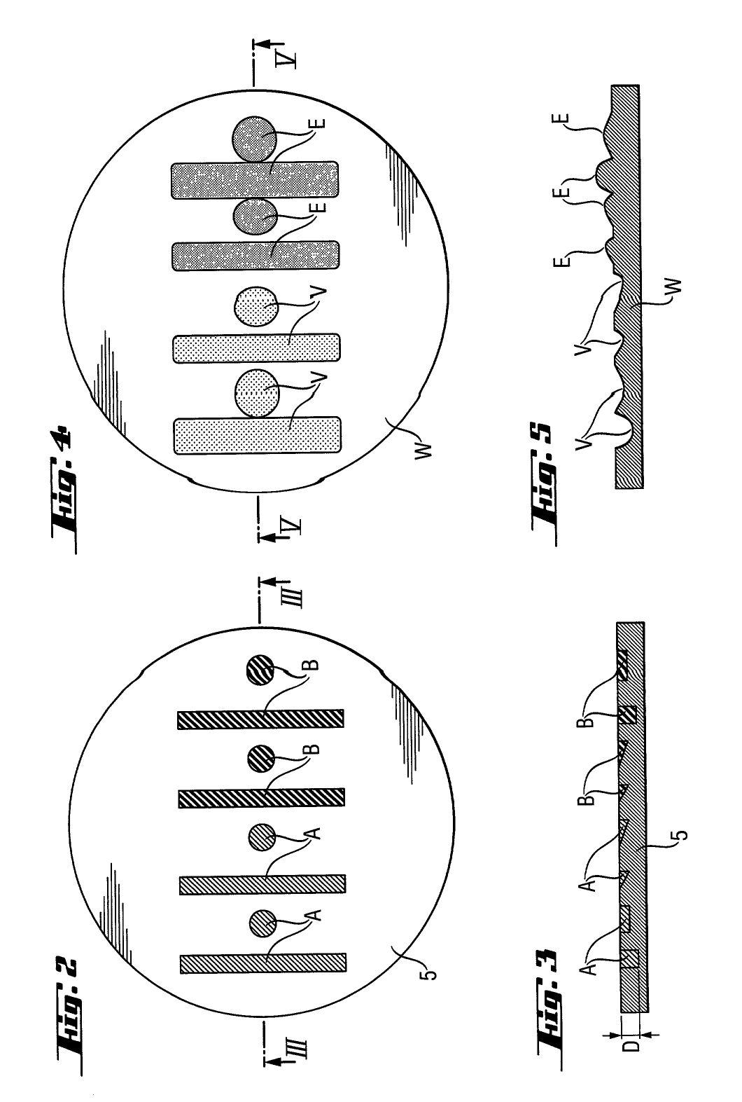

According to a further embodiment of the invention, local variations in the heat transmission are achieved by providing the bearing surface of the susceptor with depressions or elevations. Methods for producing the depressions or elevations can be, in particular: boring, sawing, milling, etching, laser ablation. The heat transmission onto the substrate lying on the susceptor is influenced by the geometrical shape of the depression or elevation. Illustrated in FIGS. 2 and 3 is a susceptor 5 in whose surface depressions with a depth D are recessed. The content of the depressions, which is denoted by material A and material B, is the surrounding atmosphere in this case. The depth D and the lateral extent of the depressions influence the temperature gradient on the substrate, and thus the shape of the epitaxially applied structures.

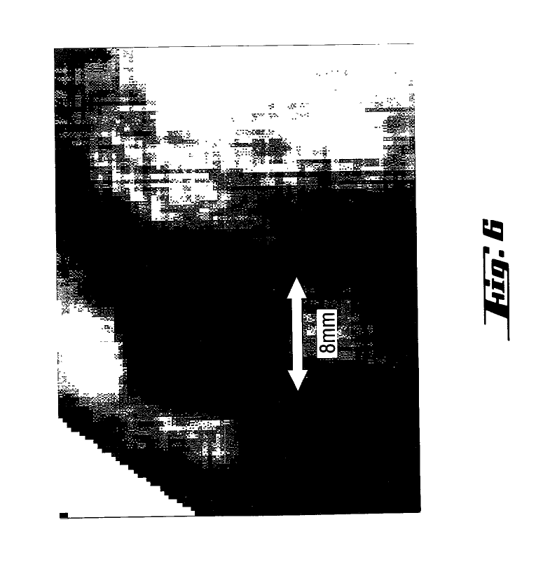

FIGS. 4 and 5 show the layer deposited on the substrate, and its structuring caused by the characteristics of the susceptor. It is clear that the invention makes accessible substrates which bear reproducible structures whose geometrical shapes and profiles, such as heights, widths and lengths, can be predetermined. Thus, a circular depression in the susceptor leads to a circular structure on the standard obtained by coating, and an elongate depression leads to an elongate structure. The thickness D of the depression in the susceptor influences the vertical extent of the corresponding nanotopographic structure on the standard.

FIGS. 4 and 5 also make it clear that a depression in the susceptor need not necessarily lead to a depression V in the deposited layer, but can also effect a structure in the form of an elevation E. This is rendered possible by virtue of the fact that, as already mentioned, further measures are combined in addition to the provision of the depression in the susceptor. For example these measures include silvering the depression in the susceptor, or feeding the radiant heat from above and below at a different intensity. If, for example, the heat dissipation at the site of the depression in the susceptor is less than in the environment of the depression, the deposition rate is increased at the site of the substrate below which the depression in the susceptor is located.

According to a further embodiment of the invention, local variations in the heat transmission are achieved by utilizing properties such as thermal conductivity and emission behavior and their dependence on material. Thus, it is possible to fill up the abovementioned depressions in the susceptor with a material A or a material B with a different coefficient of thermal conductivity. Thus it is possible to prepare a susceptor by means of which, during an epitaxy pass, a positive temperature gradient is produced at one site and a negative temperature gradient is produced at another site of the substrate. In this way, elevations and depressions can likewise be obtained on a substrate. The filling up of the depressions is performed, for example, by interference fitting or coating. SiO₂, SiC, graphite and tungsten are particularly suitable as filling materials for depressions.

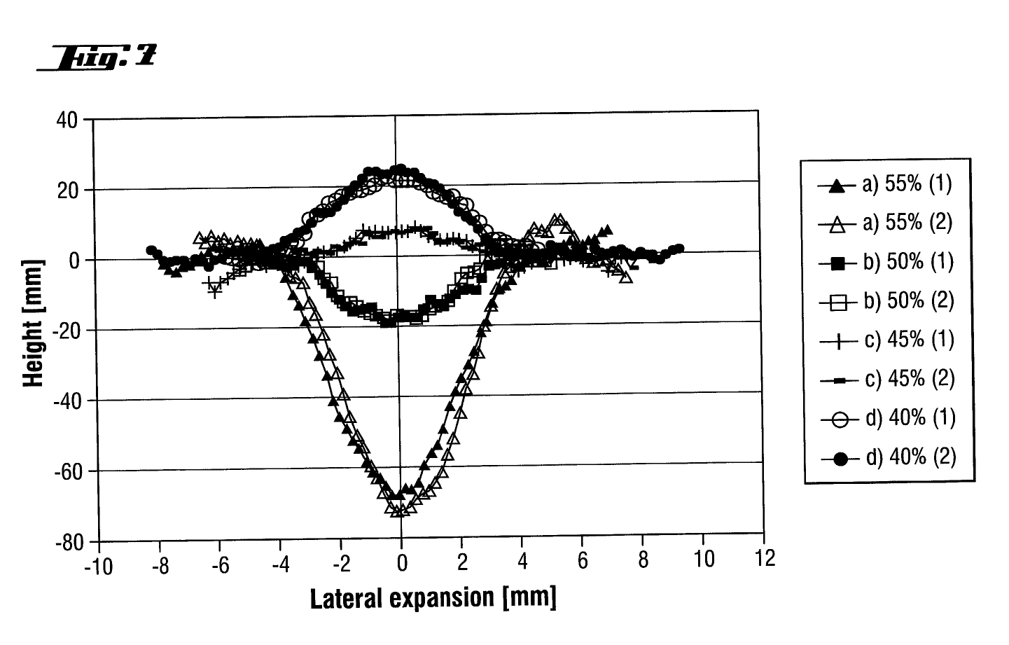

FIG. 6 shows a plan view of the projection of a deposited structure which has been measured with a nanotopography measuring system. It was produced according to the following example as a silicon structure on a semiconductor wafer made from silicon, using an epitaxy method.

The invention is described in more detail below with reference to the Example of the particularly preferred epitaxial deposition of silicon on a semiconductor wafer made from silicon. Reference is made in this Example to the drawings.

### EXAMPLE

The silicon epitaxy with SiHCl₃-enriched H₂ was performed subsequent to a preceding H₂ annealing at a temperature of approximately 1100° C. at a mean growth rate of approximately 3.5-4 μm/min. The epitaxy reactor had the features shown in FIG. 1. The deposition temperature was monitored by measuring the temperature of the wafer surface with a pyrometer from above, and by controlling the lamp power, the ratio of the upper to the lower lamp power being adjustable. If the sum of the upper and lower lamp powers which is required to achieve the deposition temperature (for example 1050-1180° C., typically 1100° C.) is denoted by 100%, it is advantageous for the power to be split respectively to approximately 50% (upper and lower power). Thus a uniform irradiation from above and below is achieved and the wafer is uniformly heated. It had been shown in experiments that increasing the lamp power from below while simultaneously reducing the lamp power from above (for example ratio below 60%, above 40%) produces a situation in which the susceptor is warmer than the wafer by a few degrees (1-10° C., typically 3-5°). As a result, the heat transmission to the wafer is reduced, for example, at sites of depressions on the susceptor. This produces a colder wafer temperature at this site, and this in turn entails a slower growth rate, and thus a smaller layer thickness. The susceptor used in the example had a circular depression at several positions. Both circular depressions and elevations were produced on the substrate, depending on the supply of energy via the infrared lamps. The proportion of the total energy supply from the lower lamps was: 55% (FIG. 7, a), 50% (FIG. 7, b), 45% (FIG. 7, c) and 40% (FIG. 7, d).

The example shows that the heights or depths of the structures produced can be controlled via the lamp irradiation. By contrast, the diameter of the structures can be set via the diameter of the depression in the susceptor. FIG. 7 illustrates sections through in each case two structures ((1), (2)), which were applied in the same process at different positions of the substrate. The very high degree of comparability of the sections illustrates the homogeneity of the process and its reproducibility.

The invention therefore makes available standards and test standards for surface topography in the wafer, CD, disk, glass and optical industries. In addition to nanotopography, the standards can also be used in geometrical measurement.

Accordingly, while a few embodiments of the present invention have been shown and described, it is to be understood that many changes and modifications may be made thereunto without departing from the spirit and scope of the invention as defined in the appended claims.

What is claimed is:

1. A standard for calibrating and checking a nanotopography unit, comprising
a substrate; and
at least one structure which is deposited on the substrate and has a lateral extent of 0.5 to 20 mm and a vertical extent of 5 to 500 nm and which is bounded by edges which have a gradient of at most 1*10⁻³.

2. The standard as claimed in claim 1,
wherein the substrate comprises a material which is selected from the group consisting of silicon, gallium arsenide, glass, silicon carbide and silicon dioxide.

3. The standard as claimed in claim 1,
wherein the structure comprises a material which is selected from the group consisting of silicon, gallium arsenide, germanium, carbon, aluminum, copper, gold, silver, silicon dioxide, silicon nitride, tungsten silicide and mixtures of said material.

4. The standard as claimed in claim 1,
wherein the structure is an elevation in a flat environment.

5. The standard as claimed in claim 1,
wherein the structure is a depression in a flat environment.

6. The standard as claimed in claim 1,
wherein the structure has a symmetrical shape.

7. The standard as claimed in claim 1,
wherein the structure has an asymmetrical shape.

8. A method for producing a standard for calibrating and checking a nanotopography unit, comprising
depositing on a substrate a material which produces at least one structure which has a lateral extent of 0.5 to 20 mm and a vertical extent of 5 to 500 nm and is bounded by edges which have a gradient of at most 1*10^{-3; and}
depositing said material on said substrate at an inhomogeneous deposition rate.

9. The method as claimed in claim 8, comprising
achieving the inhomogeneous deposition rate by a local variation of at least one parameter which is selected from the group consisting of temperature, gas pressure, gas flow, a type of gas, gas concentration, electric voltage, and strength of electric and magnetic fields.

10. The method as claimed in claim 8,
wherein a deposition method is used which is selected from the group consisting of CVD (chemical vapor deposition), electrolytic deposition, plasma coating, evaporation deposition and epitaxy.

11. The method as claimed in claim 8, comprising
depositing the structure epitaxially; and
arranging the substrate above a susceptor which has been processed locally differently in a surface region.

12. The method as claimed in claim 11, comprising
providing the susceptor locally with a depression in the surface region.

13. The method as claimed in claim 12, comprising
filling the depressing with a material foreign to the substrate.

14. The method as claimed in claim 11, comprising
providing the substrate locally with an elevation in the surface region.

15. The method as claimed in claim 11, comprising
polishing the susceptor locally differently in the surface region.

16. The method as claimed in claim 11, comprising
roughening the susceptor locally differently in the surface region.

17. The method as claimed in claim 11, comprising
silvering the susceptor locally differently in the surface region.

18. The method as claimed in claim 11, comprising
blackening the susceptor locally differently in the surface region.
